(19) United States
(12) Patent Application Publication
(10) Pub. No.: US 2004/0209123 A1
(43) Pub. Date: Oct. 21, 2004

(54) Method of fabricating a discrete track recording disk using a bilayer resist for metal lift-off

(76) Inventors: Christopher H. Bajorek, Los Gatos, CA (US); Gerardo A. Bertero, Redwood City, CA (US); Andrew Homola, Morgan Hill, CA (US)

Correspondence Address: Daniel E. Ovanezian, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/418,436

(22) Filed: Apr. 17, 2003

(51) Int. Cl. G03F 7/20; G11B 7/24

(52) U.S. Cl. 428/694 TP; 430/324; 430/320

(57) ABSTRACT

A DTR patterned magnetic recording disk having a carbon overcoat is described. The carbon overcoat may be deposited above the data storage layers to maximize edge coverage of the discrete track areas. The DTR pattern may be formed using a bilayer resist film for lift-off of above deposited metal and carbon layers.

### TECHNICAL FIELD

Embodiments of this invention relate to the field of magnetic recording disks and, more specifically, to the manufacturing of magnetic recording disks.

### BACKGROUND

A disk drive system includes one or more magnetic recording disks and control mechanisms for storing data on the disks. The reading and writing of data is accomplished by flying a read-write head over the disk to alter the properties of the disk's magnetic layer. The read-write head is typically a part of or affixed to a larger body that flies over the disk, referred to as a slider.

The trend in the design of magnetic hard disk drives is to increase the recording density of a disk drive system. Recording density is a measure of the amount of data that may be stored in a given area of a disk. To increase recording density, for example, head technology has migrated from ferrite heads to film heads and later to magneto-resistive (MR) heads and giant magneto-resistive (GMR) heads.

Achieving higher areal density (i.e., the number of stored bits per unit surface area) requires that the data tracks be close to each other. Also, because the track widths are very small, any misregistration of a track (e.g., thermal expansion) may affect the writing and/or reading with the head by an adjacent track. This behavior is commonly referred to as adjacent track interference (ATI). One method for addressing ATI is to pattern the surface of the disk to form discrete data tracks, referred to as discrete track recording (DTR).

One prior DTR structure utilizes a pattern concentric raised zones and recessed zones under a magnetic recording layer. The raised zones (also known as hills, lands, elevations, etc.) are used for storing data and the recessed zones (also known as troughs, valleys, grooves, etc.) provide inter-track isolation to reduce noise. The raised zones have a width less than the width of the recording head such that portions of the head extend over the recessed zones during operation. The recessed zones have a depth relative to flight height of a recording head and raised zones. The recessed zones are sufficiently distanced from the head to inhibit storage of data by the head in the magnetic layer directly below the recessed zones. The raised zones are sufficiently close to the head to enable the writing of data in the magnetic layer directly on the raised zones.

Therefore, when data are written to the recoding medium, the raised zones correspond to the data tracks. The recessed zones isolate the raised zones (e.g., the data tracks) from one another, resulting in data tracks that are defined both physically and magnetically. Such recessed zones may also store servo information. When data are written by the head to a particular data track (raised zones), data are inhibited from being written to adjacent recessed zones because the magnetic layer, below the recessed surface zone, is too far from the head for the head to induce magnetic transitions.

Another type of DTR structure utilizes a pattern of concentric discrete zones as the recording medium. The discrete magnetic zones are disposed on the recessed areas of a non-magnetic substrate. When data are written to the recoding medium, the discrete magnetic areas correspond to the data tracks. The substrate surface areas not containing the magnetic material isolate the data tracks from one another.

With both types of prior DTR structures, the magnetic recording disk is protected by a carbon overcoat that is disposed over the entire surface of the disk. The protective overcoat serves various functions such as protecting the magnetic layer against contacts that occur in drive operations between the recording head and the disk. The overcoat also serves to protect the magnetic media from corrosion during environmental conditions that the disk drive may operate in.

### BRIEF DESCRIPTION OF THE DRAWINGS

The present invention is illustrated by way of example, and not limitation, in the figures of the accompanying drawings in which:

FIG. 1A is a cross sectional view illustrating one embodiment of a bilayer resist film disposed above a disk substrate.

FIG. 1B is a cross sectional view illustrating one embodiment of the imprinting of a bilayer resist film by an imprinting stamper.

FIG. 1C is a cross sectional view illustrating one embodiment of a preferentially descummed bilayer resist film.

FIG. 1D is a cross sectional view illustrating one embodiment of a magnetic film stack disposed over a patterned substrate.

FIG. 1E is a cross sectional view illustrating one embodiment of a patterned magnetic film after lift-off.

FIG. 2 is a flow chart illustrating one embodiment of a method of forming a discrete track recording patterned magnetic disk using a bilayer resist film for magnetic film lift-off.

FIG. 3 illustrates one embodiment of a chemical vapor deposition process.

FIG. 4 illustrates one embodiment of protection layer deposition.

FIG. 5A is a cross sectional view illustrating one embodiment of a discrete track recording pattern disk having a non-continuous protection layer.

FIG. 5B is a cross sectional view illustrating an alternative embodiment of a discrete track recording pattern disk having a non-continuous protection layer and a continuous protection layer.

FIG. 6 illustrates one embodiment of a disk drive system.

### DETAILED DESCRIPTION

In the following description, numerous specific details are set forth such as examples of specific materials or components in order to provide a thorough understanding of the present invention. It will be apparent, however, to one skilled in the art that these specific details need not be employed to practice the invention. In other instances, well known components or methods have not been described in detail in order to avoid unnecessarily obscuring the present invention.

The terms “above,” “below,” “between,” “bottom” and “top” as used herein refer to a relative position of one layer with respect to other layers. As such, for example, one layer deposited or disposed above or below another layer may be directly in contact with the other layer or may have one or more intervening layers. Moreover, one layer deposited or disposed between layers may be directly in contact with the layers or may have one or more intervening layers.

A method of fabricating a discrete track recording disk using a bilayer film technique for metal lift-off is described. In one embodiment, the method may be used to fabricate a DTR longitudinal magnetic recording disk having a nickel-phosphorous (NiP) plated substrate as a base structure. The method may also be used to fabricate a DTR perpendicular magnetic recording disk having a soft magnetic film disposed above a substrate for the base structure. The soft magnetic film in the base structure may be composed of a single soft magnetic underlayer or multiple soft magnetic underlayers having ruthenium (Ru) interlayers disposed there between.

A bilayer film for lift-off technique involves depositing a bilayer resist film on the base structure, imprinting the bilayer film, descumming the film, deposition of a metal film stack, and lifted off of the bilayer film and the above deposited film stack. The bilayer film technique provides undercutting of one the resist layers to produce a non-continuous deposited magnetic film stack. The magnetic film stack deposited above the bilayer film may be subsequently lifted off by selectively etching one or both of the resist layers of the bilayer film, resulting in a DTR patterned magnetic film stack on the base structure.

The metal film stack may include at least one protection layer comprised of a material such as carbon. The subsequent lift-off of the (e.g., carbon) protection layer(s) in metal film stack produces a magnetic recording disk having a non-continuous protection layer. In an alternative embodiment, the protection layer may be deposited subsequent to lift-off to produce a magnetic recording disk having a continuous protection layer. In yet another embodiment, additional protection layer deposition may be performed after lift-off to produce a magnetic recording disk having both continuous and non-continuous protection layers.

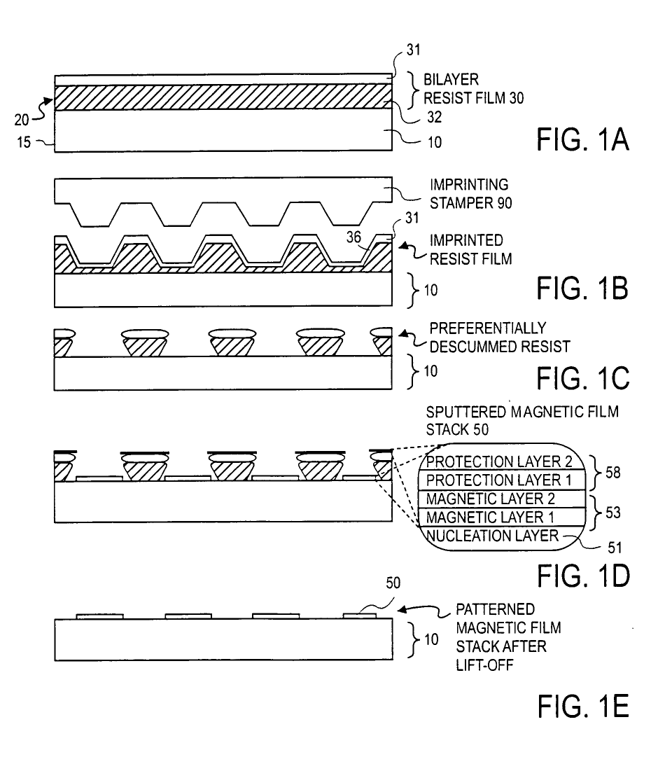

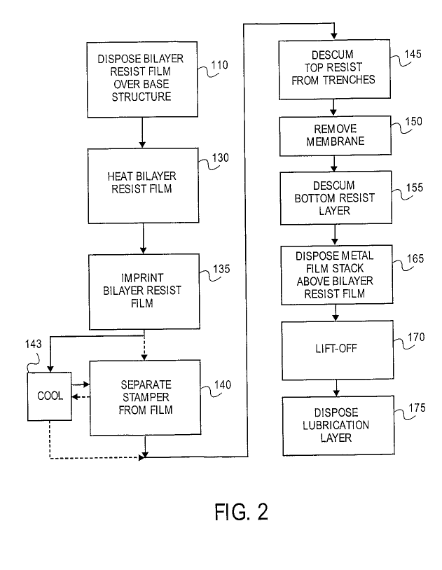

FIGS. 1A-1E and 2 illustrate one embodiment of a method of producing a discrete track recording disk using a bilayer resist for metal lift-off. In particular, FIG. 1A is a cross sectional view illustrating one embodiment of a bilayer resist film disposed above a base structure of a disk. The bilayer resist 30 provides undercutting of one of the resist layers to produce a non-continuous film stack 50 above base structure 10. The film stack 50 deposited above the bilayer film 30 may be subsequently lifted off by etching the bottom resist layer 32 of the bilayer film 30, resulting in discrete film stack areas on the base structure. In one embodiment, for example, a bilayer, nanoimprint lithography technique similar, in part, to that described in “Bilayer, Nanoimprint Lithography,” Brian Faircloth et al., J. Vac. Sci. Technol. B 18(4), July/August 2000 may be used as discussed below.

A bilayer resist film 30 is disposed above a base structure 10, step 110. In one embodiment, for example, base structure 10 may be composed of a substrate 15 and a plated NiP layer 20. Substrate 15 may be manufactured from, for examples, a glass or metal/metal alloy material. Glass substrates that may be used include, for example, a silica containing glass such as borosilicate glass and aluminosilicate glass. Metal alloy substrates that may be used include, for example, aluminum-magnesium (AlMg) substrates. In an alternative embodiment, other substrate materials including polymers and ceramics may be used.

NiP layer 20 may be formed by electroplating, electroless plating, or by other methods known in the art. Plating disk substrate 15 with a rigid or metallic material such as NiP provides mechanical support to disk substrate 15 for e.g., subsequent polishing, and/or imprinting processes. NiP layer 20 may be polished, planarized, and/or textured. NiP layer 20 may be polished, for example, by a uniform etch or other polishing techniques known in the art. NiP layer 20 may also be textured with a pattern, by various methods such as mechanical texturing using fixed or free abrasive particles (e.g., diamond). Alternatively, other types of texturing methods, such as laser texturing, may be used. Plating of disk substrate 15 may not be necessary, however, if disk substrate 15 is composed of a sufficiently rigid or hard material such as glass. Accordingly, substrate 15, itself, may be polished, planarized, and/or textured using methods described above.

In an alternative embodiment, base structure 10 may be composed of a substrate 15 having other layers disposed thereon, for examples, a soft magnetic film. Layer 20 may represent a soft magnetic film or a soft magnetic film disposed over a NiP layer. A soft magnetic film may be used to achieve the proper magnetic properties associated with perpendicular magnetic recording. The soft magnetic film 25 may be a layer of iron-copper-nickel (FeCoNi) material. Other materials that may be used for the soft magnetic film include copper-iron (CoFe) nickel-iron (NiFe), and alloys thereof. Soft magnetic films and materials that may be used for manufacturing a soft magnetic film are well known in the art of magnetic recording disks; accordingly, a detailed discussion is not provided. The soft magnetic film may be polished and/or textured. The soft magnetic film may be textured with a pattern, by various methods such as mechanical texturing using fixed or free abrasive particles (e.g., diamond). Alternatively, other types of texturing methods, such as laser texturing, may be used to texture the soft magnetic film. In yet another embodiment, a thin NiP layer may be disposed on top of the soft magnetic film and polished and/or textured. In yet another embodiment, the soft magnetic film may be composed of one or more soft magnetic underlayers and one or more Ru interlayers disposed between soft magnetic underlayers.

As previously discussed, in step 110, the bilayer resist film 30 is disposed on the base structure 10 to form an imprintable (i.e., embossable) layer. The bilayer resist film 30 is composed of a top resist layer 31 and a bottom resist layer 32. The bottom resist layer 32 has a resist material that is less resistant to etching (e.g., dry or wet) than the top resist layer. Various resist materials may be used to form the bilayer film 30. In one embodiment, for example, poly(methyl methacrylate) (PMMA) is used for bottom resist layer 32 and a co-polymer-poly(methyl methacrylate methacrylic acid copolymer) (P(MMA-MAA) is used for the top resist layer 31. Alternatively, other resist materials may be used for example, PMMA and a thermo-set polymer such as MR-I 9000 available from Micro Resists Technology of Germany. The particular resist material for the two layers 31 and 32 should be selected such that the materials do not substantially mix during either the soft baking process or when heated above their transition temperature (Tg).

In one embodiment, for example, the layers 31 and 32 are spin coated on base structure 10 to produce the bilayer film 30. The bottom resist layer 32 is first spin coated on the base structure 10. A soft bake may then be performed to drive out solvents. Next, top resist layer 31 material (e.g., P(MMA-MAA) copolymer) is spin coated onto the bottom layer 32 (e.g., PMMA). The top resist layer 31 may also be soft baked. In one embodiment, the top and bottom resist layers 31 and 32, respectively, are formed such that each layer is, for example, in the range of approximately 10 to 50 nm thick for a total film thickness in the range of approximately 20 to 100 nm. Other coating methods such as dip coating, dip-spin coating, spray coating, sputtering and vacuum deposition (e.g., CVD) may be used.

The bilayer film 30 is heated above its transition temperature, step 130, where it becomes viscoelastic. A stamper 90 is then pressed into the bilayer film 30, step 135. In one embodiment, the system is cooled, step 143, to form an imprinted pattern of trenches areas (a.k.a., recessed areas, grooves, valleys, etc.) and plateaus (a.k.a., raised areas) in the bilayer film 30 (as illustrated in FIG. 1B) and then the stamper 90 is separated from bilayer film 30, step 140. Alternatively, the stamper 90 may be separated from bilayer film 30, step 140, and then cooled, step 143, after separation. The separation of stamper 90 from bilayer film 30 before cooling may depend, in part, on the relative coefficient of thermal expansion of the stamper 90 material and the bilayer film 30 material.

In one embodiment, prior to use, the stamper 90 may be coated with a mold release polymer to facilitate separation of the stamper 90 from bilayer film 30 after imprinting. Alternate methods may be used to form the trenches, for example, using a shallow imprint followed by an etch that cuts the pattern deeper into the resist.

After stamper 90 is separated from bilayer film 30, a small amount of residual mold release polymer (not shown) may remain at the bottom of the trenches. In step 145, the trenches may be descummed (i.e., cleaned), for examples, with an oxygen plasma etch or by a wet solvent etch to remove any residual mold release polymer, as illustrated in FIG. 1C. Even if the stamper has vertical sidewalls resulting in trenches with vertical sidewalls, the descumming step 145 will round the edges of the indented structure, resulting in slightly beveled sidewalls, as illustrated in FIG. 1C.

After removing the residual mold release polymer, there is a thin membrane 36 of the top resist 31 (e.g., P(MMA-MAA)) covering the inside of the trench. This thin membrane 36 may be removed, step 150, to improve a subsequent undercutting of bottom resist 32. The membrane 36 may be removed, for example, using a wet chemical etch. A solvent (e.g., methanol) is chosen to preferentially etch the top resist (e.g., P(MMA-MAA) polymer) membrane 36 while leaving the lower resist 32 (e.g., PMMA polymer) unaffected. This is an isotropic etch that not only eliminates the thin top layer resist membrane 36 in the trenches, but also reduces the thickness of the top layer resist 31 of the bilayer resist film 30. It should be noted that membrane 36 may be removed by other types of etching methods (e.g., plasma, e-beam, ion-beam, and sputter etching).

The next step 155 in preparing the disk for metal deposition and liftoff is to descum the bottom resist layer 32 (e.g., PMMA) from the bottom of the trenches while also creating undercut in the bottom resist layer 32. Liftoff can be considerably improved when a certain amount of undercutting is produced in the bilayer film 30. Electron beam lithography and photolithography naturally produce undercutting (in positive resists) due to diffraction spreading effects for photolithography and electron scattering and secondary electron production in the resist for electron beam lithography. In imprint lithography, undercutting is achieved using a bilayer resist 30. The two materials used for the bilayer resist 30, for example, PMMA and P(MMA-MAA), are selected to have considerably different chemical properties. For example, there is a wide range of solvents that will attack PMMA, but not P(MMA-MAA) and vice versa. As such, the descumming and undercutting may be performed using a solvent (e.g., a chlorobenzene solution) that preferentially etches the bottom resist material (e.g., PMMA) while leaving the top layer resist 31 unaffected. In step 155, the disk is exposed to a solvent that will attack at a minimum the bottom resist layer 32 and maybe also the top resist layer. In this way, undercutting can be produced in the imprinted features, as illustrated in FIG. 1C. In addition, a subsequently vapor deposited metal film will not form a continuous film as long as the thickness of the deposited metal is less than that of the bottom resist layer 32. The degree of undercutting may be controlled by timing the solvent etch.

In step 165, a metal film stack 50 having one or more metal layers 53 is deposited above the undercut bilayer film 30, as illustrated in FIG. 1D. In one embodiment, the magnetic film stack 50 may include one or more nucleation layers 51 to facilitate a certain crystallographic growth within the magnetic layers 53. These layers may be of materials to provide reasonably good lattice match to the material used for the magnetic layers 53. The fabrication and composition of magnetic and nucleation layers is known in the art; accordingly, a detailed discussion is not provided.

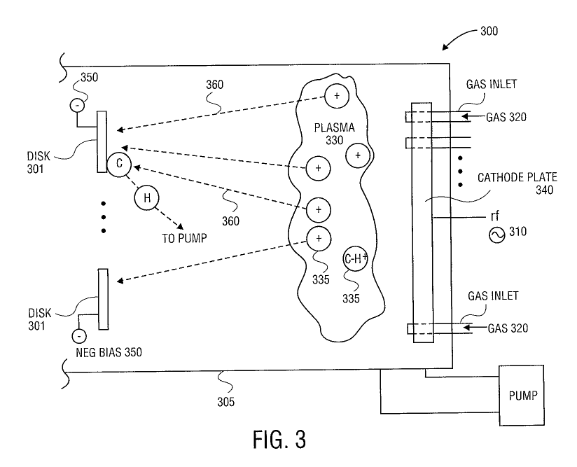

The magnetic film stack 50 may also include one or more protection layers 58 disposed above of the magnetic layers 53. For example, a dual layer protection film 58 may be disposed on top of the magnetic layers 53 to provide sufficient property to meet tribological requirements such as contact-start-stop (CSS) and corrosion protection. Predominant materials for the protection layer are carbon-based materials, such as hydrogenated or nitrogenated carbon. The protection layers may have a combined thickness, for example, of less than approximately 50 Angstroms with the thickness of the upper protection layer being, for example, less than approximately 50 Angstroms. Alternatively, the protection layers may have other thickness. In an alternative embodiment, protection film 58 may include more or less than two protection layers. The protection layer(s) may be disposed above the magnetic layers 53, for example, using chemical vapor deposition (CVD) as discussed below in relation to FIG. 3.

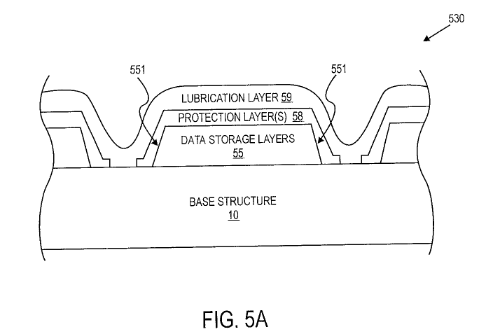

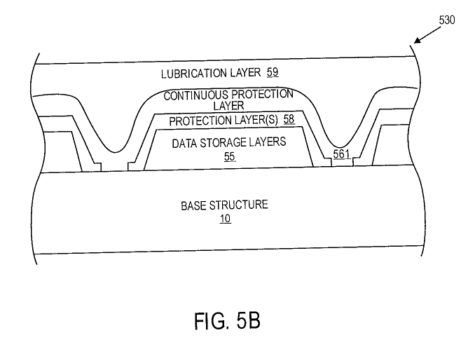

In step 170, a lift-off of magnetic film stack 50 is performed using a solvent that etches at least the bottom resist layer 32. The lift-off leaves the film stack 50 in discrete areas above base structure 10, as illustrated in FIG. 1E. The produces a DTR patterned magnetic recording disk having a non-continuous protection layer. In an alternative embodiment, one or more protection layers may not be included in film stack 50 but, rather, deposited after lift-off of the film stack 50. A lubrication layer 59 may be placed on top of the entire surface of the disk, as discussed in relation to FIGS. 5A and 5B below, to further improve tribological performance. The lubrication layer 59 may be composed of, for examples, a perfluoropolyether or phosphozene lubricant. Alternatively, other lubricant materials may be used for lubrication layer 59. The lubrication layer 59 may be disposed on the disk, step 175, using various methods, for examples, spin coating, dip coating, spin-dip coating, etc. Lubrication layers and materials are known in the art; accordingly, a detailed discussion is not provided.

It should be noted that various cleaning and/or polishing operations may be performed in between the stages discussed above, for example, to remove asperities from the surface of one or more of the layers.

FIG. 3 illustrates one embodiment of a chemical vapor deposition process. In one particular embodiment, a plasma enhanced CVD (PECVD) system 300 may be used. PECVD systems are commercially available, for example, from Anelva Corporation of Tokyo, Japan. In this exemplary embodiment, the PECVD process uses radio frequency (rf) excitation 310 of a carbon containing gas 320 to create a plasma 330 containing ionized carbon molecules 335, as illustrated in FIG. 3. In one particular embodiment, a hydrogenated carbon gas, for examples, ethylene, acetylene, butane naphthalene or others may be used. FIG. 3 illustrates only a single side of the deposition chamber 305 for ease of illustration. The non-illustrated side of the chamber operates, and has components, similar to the illustrate side such that both sides of a disk 301 may be coated simultaneously to produce a double sided disk. The rf power is applied to a carbon plate 340 that acts as a cathode. The rf power causes plasma 330 to form in front of the cathode plate 340 to create positively charged hydrocarbon gas ions 335. An Anelva PECVD system is a static deposition system in which the substrate is held stationary in front of the cathode. In one embodiment, the disks 301 are heated to a temperature in the range of approximately 170 to 500 degrees C. and the system is pressurized in the range of approximately 15-50 milli-Torr. Alternatively, the system may be pressurized to a pressure greater than 50 or less than 15 milli-Torr. The ionized hydrocarbon molecules 335 decompose into carbon on the surface of the disks 301. In one embodiment, a bias potential 350 (e.g., approximately −200 V to −400 V) is applied to the disks 301 in order to promote attraction of the positively charged ion molecules 335 to the surface of the disk and, in particular, towards the surface beneath the undercut ledges top resist layer 31. Alternatively, a larger bias potential may be used, for example, upwards of −600 V.

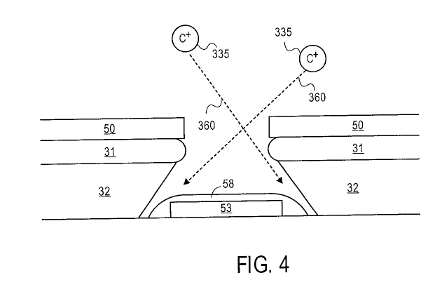

As discussed above, the CVD deposition system is pressurized during operation. The pressure of the deposition system affects the mean free path of the ionized hydrocarbon molecules 335. The higher the pressure of the system during deposition, the greater the degree of non-linear (e.g., dashed lines 360) deposition. A non-linear deposition may promote formation of the carbon layer beneath the undercut ledges of top resist layer 31, as illustrated in FIG. 4. A static CVD deposition system typically operates at a higher pressure than a sputtering or IBD system. A sputtering or IBD system typically operates at a pressure of less than 3 milliTorr. However, sputtering (e.g., DC, AC, or AC/DC sputtering), high energy (pulsed) sputtering, and ion beam deposition (IBD) processes using either static or in-line systems may also be used for deposition of the protection layer(s).

Static sputter systems are available from manufacturers such as Intevac Inc. of Santa Clara, Calif., Balzers Process Systems, Inc. of Alzenau, Germany. With in-line sputtering systems, disk substrates are loaded on a pallet that pass through a series of deposition chambers the deposit films successively on the substrates. In-line sputtering systems are available form Ulvac Corp. of Japan. It should be noted that other temperatures, pressures, biases, and thickness than provided in the exemplary embodiment above may be used, in particular, when other systems and methods are used.

In an alternative embodiment, the typically pressures that the systems are operated with may be increased to alter the mean free path of the molecules to obtain a greater degree of deposition in a non-linear direction to promote formation of the protection (e.g., carbon) layer beneath the undercut ledges top resist layer 31. For example, with a PECVD system, the pressure of the deposition system may be increased upwards of approximately 60 milli-Torr. Increased pressures may also be used in other types of deposition systems, for example, upwards of 3 milliTorr with sputtering or IBD systems.

FIG. 5A is a cross section illustrating one embodiment of a disk having a non-continuous protection layer. In one embodiment, magnetic recording disk 530 includes a base structure 10, data storage layers 55, protection layer(s) 58, and lubrication layer 59. In one embodiment data storage layers 55 may include the nucleation layer 51 and/or one or more of the magnetic layers 53 discussed above in relation to FIG. 1D. Protection layer(s) 58 may include one or more protection layers that are non-continuously disposed above base structure 10. In one embodiment, protection layers 58 may cover the edges 551 of data storage layers 55 and contact base structure 10. Base structure 10 may be composed of various layers and materials as discussed above. In an alternative embodiment, one or more continuous protection layer(s) 561 may be disposed beneath the lubrication layer 59 and above the non-continuous protection layers 58, as illustrated in FIG. 5B. In yet another embodiment, a protection layer may be continuously disposed above base structure 10 and data storage layers 55.

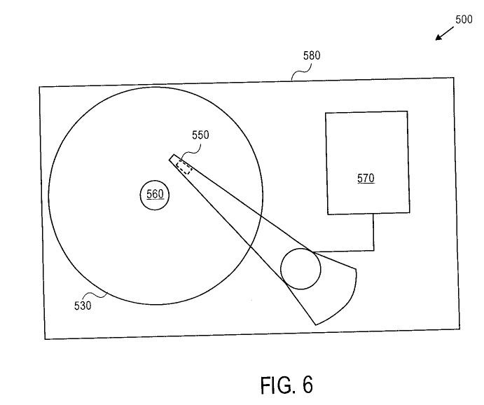

FIG. 6 illustrates a disk drive having disk (e.g., disk 530) with a non-continuous protection layer. Disk drive 500 may include one or more disks to store data. The disk(s) 530 reside on a spindle assembly 560 that is mounted to drive housing 580. Data may be stored along tracks in the magnetic recording layer of the disk(s) 530. The reading and writing of data is accomplished with head 550 that has both a read and write element. The write element is used to alter the properties of the magnetic recording layer of disk 530. In one embodiment, the read element head 550 may be a magneto-resistive (MR) and, in particular, a giant magneto-resistive (GMR) read element. In an alternative embodiment, head 550 may be another type of head, for example, a head having an inductive read element or a hall effect head. A spindle motor (not shown) rotates spindle assembly 560 and, thereby, the disk(s) 530 to position head 550 at a particular location along a desired disk track. The position of head 550 relative to the disk may be controlled by position control circuitry 570.

In the foregoing specification, the invention has been described with reference to specific exemplary embodiments thereof. It will, however, be evident that various modifications and changes may be made thereto without departing from the broader spirit and scope of the invention as set forth in the appended claims. The specification and figures are, accordingly, to be regarded in an illustrative rather than a restrictive sense.

What is claimed is:

1. A method of fabrication, comprising:
disposing a bilayer resist film above a base structure, wherein the base structure comprises a substrate; and
forming a discrete track recording pattern on a magnetic recording disk having the base structure, wherein the discrete track pattern is formed using a bilayer resist film to lift-off a magnetic layer disposed above the bilayer resist film.

2. The method of claim 1, wherein forming comprises:
imprinting the bilayer resist film;
selectively etching layers of the bilayer resist film to form a pattern of areas above the base structure that do not have the bilayer resist thereon; and
disposing a magnetic layer above the base structure in the areas that do not have the bilayer resist.

3. The method of claim 2, wherein the method further comprises disposing a protection layer over the magnetic layer in at least areas that do not have the bilayer resist to form a non-continuous protection layer above the substrate, wherein the protection layer comprises carbon.

4. The method of claim 3, wherein the magnetic layer has edges and wherein the method comprises disposing the protection layer over the edges of the magnetic layer.

5. The method of claim 4, further comprising disposing the protection layer in direct contact with the base structure.

6. The method of claim 5, wherein the base structure comprises a NiP layer plated over the substrate and wherein disposing the protection layer comprises disposing the protection layer in direct contact with the NiP layer.

7. The method of claim 5, wherein the base structure comprises a soft magnetic underlayer disposed over the substrate and wherein disposing the protection layer comprises disposing the protection layer in direct contact with the soft magnetic underlayer.

8. The method of claim 3, wherein forming further comprises:
disposing the magnetic layer above the bilayer film; and
disposing the protection layer above the magnetic layer residing above the bilayer film.

9. The method of claim 8, wherein forming further comprises lifting off the protection layer disposed above the bilayer resist film.

10 The method of claim 9, further comprising disposing a lubrication layer above the non-continuous protection layer.

11. The method of claim 9, further comprising disposing a continuous protection layer comprising carbon above the non-continuous protection layer.

12. The method of claim 10, comprising disposing a lubrication layer above the continuous protection layer.

13. The method of claim 3, wherein disposing the protection layer comprises depositing the protection layer using chemical vapor deposition at a pressure greater than 40 milliTorr.

14. The method of claim 13, wherein disposing the protection layer further comprises biasing the base structure to a potential of approximately −220 volts.

15. The method of claim 13, wherein disposing the protection layer further comprises biasing the base structure to a potential in the range of approximately −400 to −600 volts.

16. The method of claim 3, wherein disposing the protection layer comprises depositing the protection layer using chemical vapor deposition at a pressure of approximately 60 milliTorr.

17. The method of claim 1, wherein forming comprises:
imprinting the bilayer resist with a stamper; and
separating the stamper from the bilayer resist;
cooling the stamper and the bilayer resist after separation.

18. An apparatus, comprising:
means for disposing a bilayer resist film above a base structure, wherein the base structure comprises a substrate; and
means for forming a discrete track recording pattern on a magnetic recording disk having the base structure, wherein the discrete track pattern is formed using a bilayer resist film to lift-off a magnetic layer disposed above the bilayer resist film.

19. The apparatus of claim 18, wherein the means for forming comprises:
means for imprinting the bilayer resist film;
means for selectively etching layers of the bilayer resist film to form a pattern of areas above the substrate that do not have the bilayer resist thereon; and
means for disposing a magnetic layer above the base structure in the areas that do not have the bilayer resist.

20. The apparatus of claim 19, further comprising means for disposing a protection layer over the magnetic layer in areas that do not have the bilayer resist to form a non-continuous protection layer above the substrate, wherein the protection layer comprises carbon.

21. The apparatus of claim 20, wherein the magnetic layer has edges and wherein the apparatus comprises means for disposing the protection layer over the edges of the magnetic layer.

22. A magnetic recording disk, comprising:
a magnetic recording layer having a discrete track recording pattern; and
a non-continuous protection layer disposed above the magnetic recording layer, wherein the protection layer comprises carbon.

23. The magnetic recording disk of claim 22, wherein the magnetic recording layer has edges and the protection layer covers the edges of the magnetic recording layer.

24. The magnetic recording disk of claim 23, further comprising a lubrication layer above the protection layer.

25. The magnetic recording disk of claim 23, further comprising a soft magnetic layer below the magnetic recording layer, wherein the protection layer is in contact with the soft magnetic underlayer.

26. The magnetic recording disk of claim 25, further comprising a lubrication layer above the protection layer.

27. The magnetic recording disk of claim 23, further comprising a NiP layer below the magnetic recording layer, wherein the protection layer is in contact with the NiP layer.

28. The magnetic recording disk of claim 26, further comprising a lubrication layer above the protection layer.

29. The magnetic recording disk of claim 23, further comprising a substrate below the magnetic recording layer, wherein the protection layer is in contact with the substrate.

30. The magnetic recording disk of claim 29, further comprising a lubrication layer above the protection layer.

31. The magnetic recording disk of claim 22, further comprising:
a continuous protection layer disposed above the non-continuous protection layer, wherein the continuous protection layer comprises carbon.

32. The magnetic recording disk of claim 22, wherein the magnetic layer has edges and the non-continuous protection layer covers the edges of the magnetic layer.

33. The magnetic recording disk of claim 32, further comprising a lubrication layer above the protection layer.

34. A disk drive, comprising:
a magnetic recording disk, comprising:
a magnetic recording layer having a discrete track recording pattern; and
a non-continuous protection layer disposed above the magnetic recording layer, wherein the protection layer comprises carbon; and
a head having a magneto-resistance read element operatively coupled to the magnetic recording disk.

35. The disk drive of claim 34, wherein the magnetic recording layer has edges and the non-continuous protection layer covers the edges of the magnetic recording layer.

36. The disk drive of claim 35, wherein the magnetic recording disk further comprises a soft magnetic layer below the magnetic recording layer, wherein the protection layer is in contact with the soft magnetic underlayer.

37. The disk drive of claim 35, wherein the magnetic recording disk further comprises a NiP layer below the magnetic recording layer, wherein the protection layer is in contact with the NiP layer.

38. The disk drive of claim 35, wherein the magnetic recording disk further comprises a substrate below the magnetic recording layer, wherein the protection layer is in contact with the substrate.

39. The disk drive of claim 34, wherein the magnetic recording disk further comprises a continuous protection layer disposed above the non-continuous protection layer, wherein the continuous protection layer comprises carbon.

40. The disk drive of claim 34, wherein the magnetic layer has edges and the non-continuous protection layer covers the edges of the magnetic layer.
